(19) United States
(12) Patent Application Publication
(10) Pub. No.: US 2025/0287480 A1
(43) Pub. Date: Sep. 11, 2025

(54) MICROWAVE UNIT AND SUBSTRATE PROCESSING APPARATUS INCLUDING THE SAME

(71) Applicant: SEMES CO., LTD., Cheonan-si (KR)

(72) Inventors: Yoon SEOK CHOI, Cheonan-si (KR); Han Lim KANG, Cheonan-si (KR)

(73) Assignee: SEMES CO., LTD., Cheonan-si (KR)

(21) Appl. No.: 19/070,917

(22) Filed: Mar. 5, 2025

(30) Foreign Application Priority Data
Mar. 5, 2024 (KR) 10-2024-0031411

(51) Int. Cl. H05B 6/76; H01J 37/32; H05B 6/72

(52) U.S. Cl. CPC H05B 6/766; H01J 37/32449; H01J 37/32522; H05B 6/72; H01J 2237/3341

(57) ABSTRACT

Disclosed are a microwave unit and a substrate processing apparatus including the same. The microwave unit includes a microwave generator configured to generate microwaves, a waveguide configured to guide the microwaves, an antenna configured to transmit the microwaves, and a window member configured to allow the microwaves to pass therethrough. The window member includes a coating layer formed on the upper surface thereof.

### CROSS-REFERENCE TO THE RELATED APPLICATION

The present application claims priority to and the benefit of Korean Patent Application No. 10-2024-0031411, filed on Mar. 5, 2024, in the Korean Intellectual Property Office, the entire disclosure of which is incorporated herein by reference.

### BACKGROUND

### 1. Field

The present disclosure relates to a microwave unit and a substrate processing apparatus including the same. More particularly, the present disclosure relates to a substrate processing apparatus capable of evenly heating a substrate using microwaves.

### 2. Description of the Related Art

In general, semiconductor chips are manufactured through a series of processes, for example, a process of depositing a thin film on the surface of a substrate, an etching process, a cleaning process, and a drying process. During these processes, the substrate needs to satisfy optimal conditions for implementation of each process. For example, the etching or deposition process is implemented through a physical or chemical method. The substrate may be heated to an appropriate temperature in order to activate reaction between the substrate and an etchant or a material for deposition.

Among various methods of increasing the temperature of a substrate, a substrate processing apparatus using plasma employs a method of increasing the temperature of a substrate using a heating means (heating wire) of a substrate support unit on which the substrate is placed. In the case of the conventional substrate heating method using a heater, it takes a long time to increase and lower temperature, and it is difficult to evenly heat the entirety of a substrate.

As a conventional method for solving this problem, a method of heating a substrate using a microwave unit in an upper side of a chamber has been proposed.

FIG. 1 is a view schematically showing a conventional substrate processing apparatus.

As shown in FIG. 1, the substrate processing apparatus 1 may include a chamber 100, a substrate support unit 200, a microwave unit 500, and a window member 600. When a substrate W is heated using the microwave unit 500, microwaves generated by the microwave unit 500 pass through the window member 600 and reach the substrate W, thereby heating the substrate W. This method shortens a time required for heating, but has a problem in that there is a temperature difference between regions of the substrate W because the microwaves do not evenly reach the entire surface of the substrate W. In detail, depending on modes in which the microwave unit 500 supplies microwaves to the interior of the chamber 100, the peripheral region W2 of the substrate W is heated earlier than the other region of the substrate W, or the central region W1 of the substrate W is heated earlier than the other region of the substrate W. Accordingly, the temperature of the central region W1 of the substrate W and the temperature of the peripheral region W2 of the substrate W differ from each other, causing defects in a semiconductor and leading to reduction in yield.

Therefore, there is a demand for new technology for evenly transmitting microwaves generated by a microwave unit to the entire surface of a substrate.

### SUMMARY

The present disclosure has been made to solve the above problems, and an aspect of the present disclosure is directed to providing a microwave unit and a substrate processing apparatus including the same capable of transmitting microwaves supplied to a processing space in a chamber to a substrate, thereby improving temperature uniformity of the entire surface of the substrate.

The aspects of the present disclosure are not limited to the aspect mentioned above, and other aspects not mentioned herein will be clearly understood by those skilled in the art from the following description.

A microwave unit according to an embodiment of the present disclosure includes a microwave generator configured to generate microwaves, a waveguide configured to guide the microwaves, an antenna configured to transmit the microwaves, and a window member configured to allow the microwaves to pass therethrough, wherein the window member includes a coating layer formed on the upper surface thereof.

In one embodiment, the coating layer may be formed of a metallic material.

In one embodiment, the coating layer may include a grid pattern.

In one embodiment, the antenna may have a torus shape and may include a plurality of output slots formed in the inner periphery thereof.

In one embodiment, the plurality of output slots may be disposed so as to be spaced apart from each other at predetermined intervals along the inner periphery of the antenna.

In one embodiment, the window member may have a disc shape, and the inner periphery of the torus-shaped antenna and the outer periphery of the window member may be in contact with each other.

In one embodiment, the microwaves supplied through the plurality of output slots may be introduced into the window member to cause a surface plasmon resonance phenomenon at an interface between the window member and the coating layer.

A substrate processing apparatus according to an embodiment of the present disclosure includes a chamber including a processing space defined therein, a substrate support unit disposed in the processing space to support a substrate, a gas supply unit configured to supply a gas to the processing space, a plasma generation unit configured to convert the supplied gas into plasma, a microwave unit configured to supply microwaves to the processing space, and a controller configured to control the plasma generation unit, the gas supply unit, and the microwave unit, wherein the microwave unit includes a microwave generator configured to supply microwaves to the processing space, a waveguide configured to guide the microwaves, an antenna configured to transmit the microwaves, and a window member configured to allow the microwaves to pass therethrough, and the window member includes a coating layer formed on the upper surface thereof.

In one embodiment, the coating layer may be an upper electrode configured to generate plasma in the processing space.

In one embodiment, the chamber may include a body part having an open upper surface, a cover part provided on the upper end of the body part to seal the open upper surface of the body part, and a support part protruding from the body part to the processing space.

In one embodiment, the support part may support at least a portion of the antenna and at least a portion of the window member.

In one embodiment, the gas supply unit may be connected to the support part.

In one embodiment, the controller may perform control such that the gas supply unit is not driven while the microwave unit is driven.

In one embodiment, the controller may control the plasma generation unit and the gas supply unit to generate plasma of a gas supplied to the processing space, thereby modifying a thin film formed on the substrate, and may control the microwave unit to supply the microwaves to the processing space, thereby etching the modified thin film.

A substrate processing apparatus according to an embodiment of the present disclosure includes a chamber including space defined therein, a substrate support unit disposed in the processing space to support a substrate, a gas supply unit configured to supply a gas to the processing space, a plasma generation unit configured to convert the supplied gas into plasma, a microwave unit configured to supply microwaves to the processing space, and a controller configured to control the plasma generation unit, the gas supply unit, and the microwave unit, wherein the microwave unit includes a microwave generator configured to generate microwaves in the processing space, a waveguide configured to guide the microwaves, an antenna configured to transmit the microwaves, and a window member having a disc shape and configured to allow the microwaves to pass therethrough, the window member includes a coating layer formed on the upper surface thereof, the antenna has a torus shape and includes a plurality of output slots formed in the inner periphery thereof, and the microwaves supplied through the plurality of output slots are introduced into the window member to cause a surface plasmon resonance phenomenon at an interface between the window member and the coating layer.

In one embodiment, the coating layer may be formed of a metallic material.

In one embodiment, the coating layer may include a grid pattern.

In one embodiment, the plurality of output slots may be disposed so as to be spaced apart from each other at predetermined intervals along the inner periphery of the antenna.

In one embodiment, the chamber may include a body part having an open upper surface, a cover part provided on the upper end of the body part to seal the open upper surface of the body part, and a support part protruding from the body part to the processing space, and the support part may support at least a portion of the antenna and at least a portion of the window member.

In one embodiment, the gas supply unit may be connected to the support part.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view showing a conventional substrate processing apparatus;

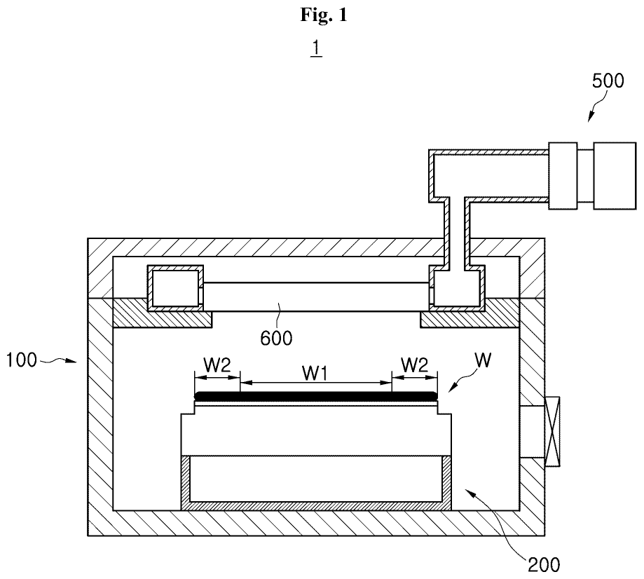

FIG. 2 is a view showing a substrate processing apparatus according to an embodiment of the present disclosure;

FIG. 3 is a view showing an antenna according to an embodiment of the present disclosure;

FIG. 4 is a view showing a window member according to an embodiment of the present disclosure;

FIG. 5 is a view showing a window member according to another embodiment of the present disclosure; and

FIG. 6 is a flowchart showing a substrate processing method according to an embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

In the following description of the embodiments of the present disclosure, a detailed description of known functions or configurations incorporated herein will be omitted when it may unnecessarily obscure the subject matter of the present disclosure. Throughout the drawings, parts performing similar functions and operations are denoted by the same reference numerals.

At least some of the terms used in this specification are terms defined taking into consideration the functions obtained in accordance with the present disclosure, and may be changed in accordance with the intention of users or operators or usual practice. Therefore, the definitions of these terms should be determined based on the total content of this specification.

As used herein, singular forms may include plural forms, unless the context clearly indicates otherwise. Additionally, the term “comprise”, “include”, or “have” described herein should be interpreted not to exclude other elements but to further include such other elements unless mentioned otherwise.

In the drawings, the sizes or shapes of elements and thicknesses of lines may be exaggerated for clarity and convenience of description.

Hereinafter, embodiments of the present disclosure will be described in detail with reference to the accompanying drawings, and the same or similar elements are denoted by the same reference numerals even though they are depicted in different drawings, and redundant descriptions thereof will be omitted.

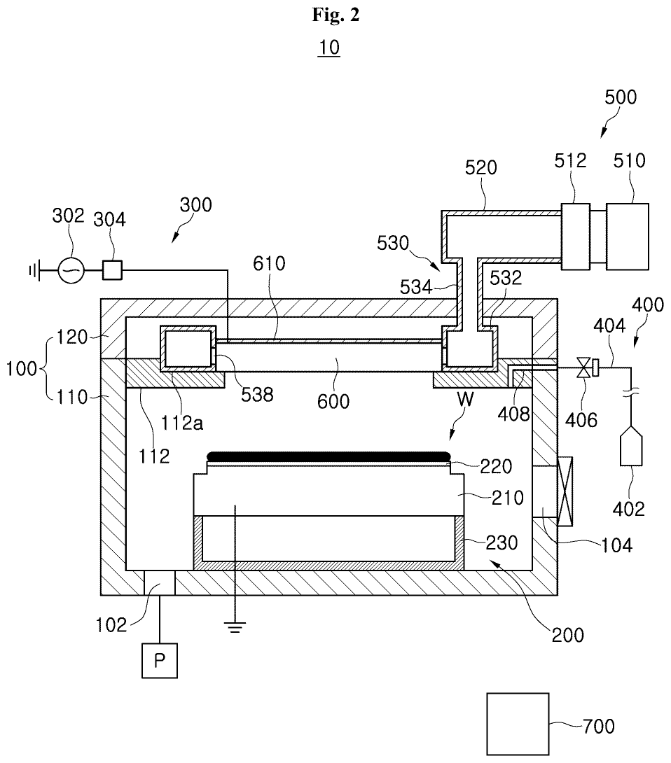

FIG. 2 is a view showing a substrate processing apparatus according to an embodiment of the present disclosure.

Referring to FIG. 2, the substrate processing apparatus 10 may include a chamber 100, a substrate support unit 200, a plasma generation unit 300, a gas supply unit 400, a microwave unit 500, and a controller 700.

The chamber 100 may have a processing space defined therein so as to allow a plasma process to be performed therein, and may include a body part 110 and a cover part 120. The body part 110 may have an open upper surface and may have an inner space defined therein. In an example, the body part 110 may have a cylindrical shape having an open upper surface and having an inner space defined therein. The cover part 120 may be provided on the upper end of the body part 110. The cover part 120 may seal the open upper surface of the body part 110. In an example, the cover part 120 may have a cylindrical shape having an open lower surface. The body part 110 and the cover part 120 may be assembled to each other to form the chamber 100.

The body part 110 of the chamber 100 may include a support part 112 connected thereto. The support part 112 may have a circular or annular shape having a hollow center. In addition, the support part 112 may have a stepped portion 112a, on which a portion of the microwave unit 500 and a portion of a window member 600, which will be described later, are placed and supported. The support part 112 may be made of a material that allows microwaves to pass therethrough, for example, ceramic, quartz, or microwave-transmissive plastic.

The chamber 100 may include an exhaust port 102 formed in a lower side thereof, and the exhaust port 102 may be connected to an exhaust line on which a pump P is mounted. The pump P may discharge reaction by-products generated during the plasma process and gas remaining in the chamber 100 to the outside of the chamber 100 through the exhaust line. In this case, pressure in the inner space in the chamber 100 may be reduced to a predetermined pressure.

The chamber 100 may include an opening 104 formed in the sidewall thereof. The opening 104 may function as a passage through which a substrate W is introduced into and discharged from the chamber 100. The opening 104 may be configured to be opened and closed by a door assembly.

The substrate support unit 200 may be disposed in a lower area in the chamber 100. The substrate support unit 200 may support the substrate W using electrostatic force. However, this embodiment is not limited thereto. The substrate W may be supported in various ways, such as mechanical clamping or vacuum support.

The substrate support unit 200 may include a support body 210 and an electrostatic chuck 220 disposed on the upper surface of the support body 210. The electrostatic chuck 220 may be configured to electrostatically attract and hold the substrate W, and may include a ceramic layer provided with an electrode.

According to an embodiment of the present disclosure, although not shown, the substrate support unit 200 may be provided therein with a heating member and a cooling member to maintain the substrate W at a process temperature. The heating member may be a heating coil, and the cooling member may be provided as a cooling line through which refrigerant flows.

A support member 230 may be provided under the support body 210 in order to support the support body 210 and the electrostatic chuck 220. The support member 230 may be formed in a cylindrical shape having a predetermined height, and may have a space defined therein.

The plasma generation unit 300 may generate plasma in the processing space in the chamber 100. Plasma may be generated in an area above the substrate support unit 200 in the chamber 100. According to an embodiment of the present disclosure, the plasma generation unit 300 may generate plasma in the processing space in the chamber 100 using a capacitively coupled plasma (CCP) source.

However, this embodiment is not limited thereto. The plasma generation unit 300 may also generate plasma in the processing space in the chamber 100 using another type of plasma source, such as an inductively coupled plasma (ICP) source or microwaves.

The plasma generation unit 300 may include a high-frequency power supply 302 and a matching device 304. The high-frequency power supply 302 may supply high-frequency power to any one of an upper electrode and a lower electrode in order to generate a potential difference between the upper electrode and the lower electrode. Here, the upper electrode may be a coating layer 610 formed on a window member 600 to be described later, and the lower electrode may be the substrate support unit 200. The high-frequency power supply 302 may be connected to the coating layer 610 formed on the window member 600, and the lower electrode may be grounded (not shown).

The gas supply unit 400 may supply gas necessary for the process to the interior of the chamber 100. The gas supply unit 400 may include a gas source 402, a gas supply line 404, and a gas supply pipe 408. The gas supply line 404 may connect the gas source 402 to the gas supply pipe 408. The gas supply line 404 may supply gas stored in the gas source 402 to the gas supply pipe 408. A gas supply valve 406 may be mounted on the gas supply line 404 in order to open and close the passage of the gas supply line 404 or to regulate the flow rate of fluid flowing through the passage. The gas supply pipe 408 may be connected to the interior of the chamber 100 through the support part 112. However, this embodiment is not limited thereto. The gas supply pipe 408 may be connected to the interior of the chamber 100 through the body part 110 of the chamber 100.

Although one gas source 402 and one gas supply valve 406 are illustrated in FIG. 2, the gas supply unit of the present disclosure may include a plurality of gas sources to supply a plurality of gases to the processing space in the chamber 100 and a plurality of gas supply valves to independently control supply of the respective gases.

The microwave unit 500 may apply microwaves to the processing space in the chamber 100. The microwave unit 500 may include a microwave generator 510, a waveguide 520, an antenna 530, and a window member 600.

The microwave generator 510 may serve to generate microwaves, and the generated microwaves may have a frequency of about 2.3 GHz to about 2.5 GHz. The microwave generator 510 may be connected to the waveguide 520, and a matching network 512 may be provided between the microwave generator 510 and the waveguide 520. The matching network 512 may match the microwaves supplied from the microwave generator 510 to a predetermined frequency.

The waveguide 520 may be formed in a tube shape having a polygonal or circular section. The waveguide 520 may include a conductive inner surface. In an example, the inner surface of the waveguide 520 may be made of metal or silver. The waveguide 520 may provide a passage through which microwaves generated by the microwave generator 510 are transmitted, and may be connected to the antenna 530.

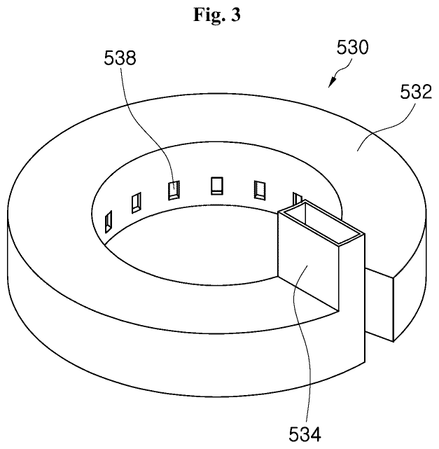

FIG. 3 is a view showing an antenna according to an embodiment of the present disclosure. The antenna may transmit microwaves generated by the microwave generator to the window member.

Referring to FIG. 3, the antenna 530 according to an embodiment of the present disclosure may include a first portion 532 and a second portion 534. The first portion 532 and the second portion 534 may be integrally formed with each other.

The first portion 532 may be formed in a torus shape, and may include a cut portion. The first portion 532 may include a plurality of output slots 538 formed in the inner periphery thereof. The output slots 538 may be formed as through-slots penetrating the side surface of the first portion 532, and may be selectively filled with a material capable of transmitting microwaves. The plurality of output slots 538 may be disposed so as to be spaced apart from each other at predetermined intervals along the inner periphery of the first portion 532. The output slots 538 may have a rectangular shape in the diameter direction of the antenna 530. However, this embodiment is not limited thereto.

The second portion 534 may extend from the first portion 532. In an example, the second portion 534 may extend upwardly from the upper surface of the first portion 532. The second portion 534 may be coupled to the upper surface of the first portion 532 at a position abutting the cut portion of the first portion 532, and may be connected to the waveguide 520 and the microwave generator 510.

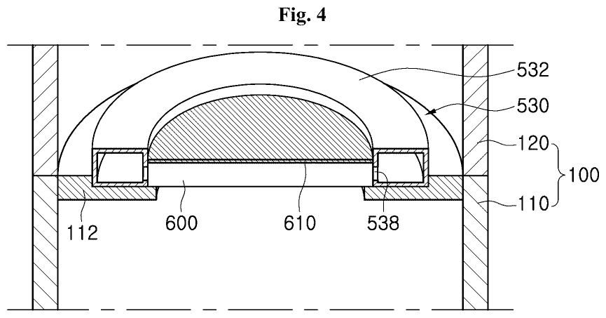

FIG. 4 is a perspective cross-sectional view showing a window member according to an embodiment of the present disclosure.

Referring to FIG. 4, the window member 600 may include a coating layer 610. The window member 600 is configured to transmit microwaves supplied from the microwave unit 500 to the substrate W without loss (or with minimal loss).

The window member 600 may have a disc shape, and the microwave unit 500 may be disposed along the periphery of the window member 600. In detail, the inner periphery of the antenna 530 of the microwave unit 500 and the outer periphery of the window member 600 may be provided in contact with each other. The window member 600 may be made of a material that allows microwaves to pass therethrough in order to heat the substrate W, and may be made of a corrosion-resistant material. The window member 600 according to the embodiment of the present disclosure may be made of quartz.

The coating layer 610 may be formed on the upper surface of the window member 600, and may have a predetermined thickness. The coating layer 610 may be formed so as to cover the entire surface of the window member 600, and may include a metal. For example, the coating layer 610 may be made of aluminum (Al) or silver (Ag). However, this embodiment is not limited thereto. Any conductive metal may be used to form the coating layer 610. The coating layer 610 may be formed through various methods, such as chemical vapor deposition (CVD), atomic layer deposition (ALD), and physical vapor deposition (PVD).

The structure in which the coating layer 610 is formed on the upper surface of the window member 600 may induce a surface plasmon resonance phenomenon. In more detail, when microwaves are supplied from the microwave unit 500, a surface plasmon resonance phenomenon may occur at the interface between the window member 600 and the coating layer 610. Here, surface plasmon resonance is a resonance phenomenon caused by matching of vibrations of electrons and electromagnetic waves at the surface/interface of a metal. Due to the surface plasmon resonance phenomenon, an electric field caused by the microwaves may be amplified over the entire area in which the coating layer 610 is formed. As a result, the microwaves applied to the entirety of the window member 600 may be evenly transmitted to the entire surface of the substrate W. Accordingly, the temperature uniformity of the entire surface of the substrate W and substrate heating efficiency may be improved.

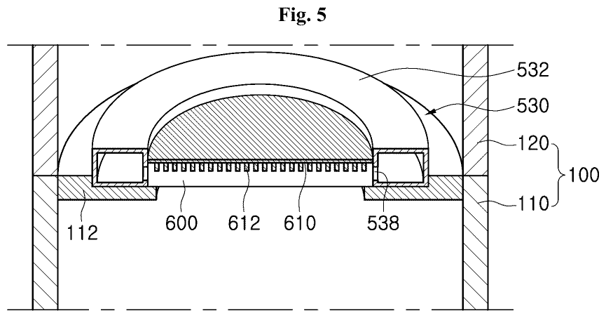

FIG. 5 is a perspective cross-sectional view showing a window member according to another embodiment of the present disclosure. Unlike the window member 600 shown in FIG. 4, the window member 600 shown in FIG. 5 may include a grid pattern 612 in addition to the coating layer 610.

Referring to FIG. 5, a grid pattern 612 may be formed under the coating layer 610. The grid pattern 612 may be integrally formed with the coating layer 610. The grid pattern 612 may be formed so as to cover the entire surface of the window member 600. An interval between bars constituting the grid pattern 612 may be similar to the wavelength of the microwaves. A surface plasmon resonance phenomenon may occur at the interface between the window member 600 and each of the coating layer 610 and the grid pattern 612 due to the microwaves. An electric field is generated by the surface plasmon resonance phenomenon, and constructive interference occurs between the electric field and the microwaves. Accordingly, the electric field may be further amplified, and as a result, the temperature uniformity of the entire surface of the substrate W heated by the microwaves and substrate heating efficiency may be improved.

Referring again to FIG. 2, the controller 700 may comprehensively control the operation of the substrate processing apparatus 10 configured as described above. The controller 700 may be, for example, a computer, and may include a central processing unit (CPU), random access memory (RAM), read only memory (ROM), and an auxiliary storage device. The CPU may operate on the basis of a program stored in the ROM or the auxiliary storage device or process conditions to control the overall operation of the apparatus 10. In addition, a computer-readable program necessary for control may be stored in a storage medium. The storage medium may include, for example, a flexible disk, a compact disc (CD), a CD-ROM, a hard disk, a flash memory, a DVD, or the like. The controller 700 may be provided inside or outside the substrate processing apparatus 10. In the case in which the controller 700 is provided outside the substrate processing apparatus 10, the controller 700 may control the substrate processing apparatus 10 using a wired or wireless communication method.

The controller 700 according to the embodiment of the present disclosure may control the plasma generation unit 300, the gas supply unit 400, and the microwave unit 500. In an example, the controller 700 may perform control such that the gas supply unit 400 supplies gas to the processing space in the chamber 100 and the plasma generation unit 300 converts the supplied gas into plasma. The controller 700 may perform control such that the gas supply unit 400 is not driven while the microwave unit 500 is driven.

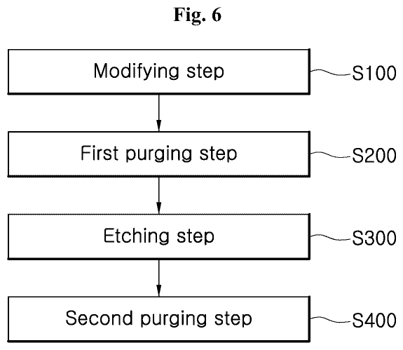

FIG. 6 is a flowchart showing a substrate processing method according to an embodiment of the present disclosure.

Referring to FIG. 6, a method of etching a thin film formed on a substrate according to an embodiment of the present disclosure may include a modifying step S100 of supplying a modifying gas to the processing space in the chamber in which the substrate is disposed to modify the substrate, a first purging step S200 of supplying a purge gas to the processing space to remove the modifying gas remaining in the processing space, an etching step S300 of supplying microwaves to the processing space to etch the modified substrate in units of atomic layers, and a second purging step S400 of supplying a purge gas to the processing space to remove etching by-products remaining in the processing space. The modifying step to the second purging step S100 to S400 may be set as one cycle, and this cycle may be repeatedly performed one or more times to etch the substrate to a desired thickness.

The modifying step S100 is a step of supplying a modifying gas to the processing space in the chamber in which the substrate is disposed to modify the substrate. The modifying gas may be supplied from the gas supply unit, and the supplied modifying gas may be converted into plasma and may then be supplied to the substrate. The modifying gas converted into plasma may cause chemical reaction with the substrate to modify the surface layer of the substrate.

The first purging step S200 is a step of supplying, by the gas supply unit, a purge gas to remove the modifying gas remaining in the chamber. The purge gas may be supplied after the supply of the modifying gas is interrupted, and may be directly supplied to the processing space in the chamber without using plasma. Due to the supply of the purge gas, the modifying gas remaining in the chamber after being supplied in the modifying step S100 and reaction by-products may be removed. An inert gas, such as argon (Ar), helium (He), or nitrogen (N₂), may be used as the purge gas.

The etching step S300 is a step of supplying microwaves to the processing space in the chamber to etch the modified substrate in units of atomic layers. The modified substrate may be etched in units of atomic layers by supplying microwaves, i.e., heat, to the substrate using the microwave unit. The microwaves supplied from the microwave unit may be supplied to the entire surface of the substrate through the window member. In detail, the microwaves cause a surface plasmon resonance phenomenon at the interface between the window member and the coating layer formed on the upper surface of the window member, whereby the electric field of the coating layer is amplified. Amplification of the electric field may improve efficiency with which the substrate is heated by the microwaves. In this way, since the coating layer is formed on the window member, heat may be evenly supplied to the entire surface of the substrate, and the entire surface of the substrate may be evenly etched.

The second purging step S400 is a step of supplying, by the gas supply unit, a purge gas to remove etching by-products remaining in the chamber. The purge gas may be supplied after the supply of the microwaves is interrupted, and may be directly supplied to the processing space in the chamber without using plasma. Due to the supply of the purge gas, etching by-products generated during the etching step S300 may be removed. An inert gas, such as argon (Ar), helium (He), or nitrogen (N₂), may be used as the purge gas.

As is apparent from the above description, according to the present disclosure, a coating layer including a metal is formed on the upper surface of a window member capable of transmitting microwaves, thereby amplifying an electric field.

In addition, an electric field in an area corresponding to the entire surface of a substrate is evenly increased due to a surface plasmon resonance phenomenon, thereby improving temperature uniformity of the entire surface of the substrate and substrate heating efficiency.

The effects achievable through the present disclosure are not limited to the above-mentioned effects, and other effects not mentioned herein will be clearly understood by those skilled in the art from the above description.

It will be apparent to those skilled in the art that various changes in form and details may be made without departing from the essential characteristics of the disclosure set forth herein. Accordingly, the above detailed description is not intended to be construed to limit the disclosure in all aspects and to be considered by way of example. The scope of the disclosure should be determined by reasonable interpretation of the appended claims and all equivalent modifications made without departing from the disclosure should be included in the following claims.

What is claimed is:

1. A microwave unit comprising:
a microwave generator configured to generate microwaves;
a waveguide configured to guide the microwaves;
an antenna configured to transmit the microwaves; and
a window member configured to allow the microwaves to pass therethrough,
wherein the window member comprises a coating layer formed on an upper surface thereof.

2. The microwave unit as claimed in claim 1, wherein the coating layer is formed of a metallic material.

3. The microwave unit as claimed in claim 1, wherein the coating layer comprises a grid pattern.

4. The microwave unit as claimed in claim 1, wherein the antenna has a torus shape and comprises a plurality of output slots formed in an inner periphery thereof.

5. The microwave unit as claimed in claim 4, wherein the plurality of output slots is disposed so as to be spaced apart from each other at predetermined intervals along the inner periphery of the antenna.

6. The microwave unit as claimed in claim 4, wherein the window member has a disc shape, and
wherein the inner periphery of the torus-shaped antenna and an outer periphery of the window member are in contact with each other.

7. The microwave unit as claimed in claim 4, wherein the microwaves supplied through the plurality of output slots are introduced into the window member to cause a surface plasmon resonance phenomenon at an interface between the window member and the coating layer.

8. A substrate processing apparatus comprising:
a chamber comprising a processing space defined therein;
a substrate support unit disposed in the processing space to support a substrate;
a gas supply unit configured to supply a gas to the processing space;
a plasma generation unit configured to convert the supplied gas into plasma;
a microwave unit configured to supply microwaves to the processing space; and
a controller configured to control the plasma generation unit, the gas supply unit, and the microwave unit,
wherein the microwave unit comprises:
a microwave generator configured to supply microwaves to the processing space;
a waveguide configured to guide the microwaves;
an antenna configured to transmit the microwaves; and
a window member configured to allow the microwaves to pass therethrough, and
wherein the window member comprises a coating layer formed on an upper surface thereof.

9. The substrate processing apparatus as claimed in claim 8, wherein the coating layer is an upper electrode configured to generate plasma in the processing space.

10. The substrate processing apparatus as claimed in claim 8, wherein the chamber comprises:
a body part having an open upper surface;
a cover part provided on an upper end of the body part to seal the open upper surface of the body part; and
a support part protruding from the body part to the processing space.

11. The substrate processing apparatus as claimed in claim 10, wherein the support part supports at least a portion of the antenna and at least a portion of the window member.

12. The substrate processing apparatus as claimed in claim 10, wherein the gas supply unit is connected to the support part.

13. The substrate processing apparatus as claimed in claim 8, wherein the controller performs control such that the gas supply unit is not driven while the microwave unit is driven.

14. The substrate processing apparatus as claimed in claim 8, wherein the controller controls the plasma generation unit and the gas supply unit to generate plasma of a gas supplied to the processing space, thereby modifying a thin film formed on the substrate, and controls the microwave unit to supply the microwaves to the processing space, thereby etching the modified thin film.

15. A substrate processing apparatus comprising:
a chamber comprising a processing space defined therein;
a substrate support unit disposed in the processing space to support a substrate;
a gas supply unit configured to supply a gas to the processing space;
a plasma generation unit configured to convert the supplied gas into plasma;
a microwave unit configured to supply microwaves to the processing space; and
a controller configured to control the plasma generation unit, the gas supply unit, and the microwave unit,
wherein the microwave unit comprises:
a microwave generator configured to generate microwaves in the processing space;
a waveguide configured to guide the microwaves;
an antenna configured to transmit the microwaves; and
a window member having a disc shape, the window member being configured to allow the microwaves to pass therethrough,
wherein the window member comprises a coating layer formed on an upper surface thereof,
wherein the antenna has a torus shape and comprises a plurality of output slots formed in an inner periphery thereof, and
wherein the microwaves supplied through the plurality of output slots are introduced into the window member to cause a surface plasmon resonance phenomenon at an interface between the window member and the coating layer.

16. The substrate processing apparatus as claimed in claim 15, wherein the coating layer is formed of a metallic material.

17. The substrate processing apparatus as claimed in claim 15, wherein the coating layer comprises a grid pattern.

18. The substrate processing apparatus as claimed in claim 15, wherein the plurality of output slots is disposed so as to be spaced apart from each other at predetermined intervals along the inner periphery of the antenna.

19. The substrate processing apparatus as claimed in claim 15, wherein the chamber comprises:
a body part having an open upper surface;
a cover part provided on an upper end of the body part to seal the open upper surface of the body part; and
a support part protruding from the body part to the processing space, and
wherein the support part supports at least a portion of the antenna and at least a portion of the window member.

20. The substrate processing apparatus as claimed in claim 19, wherein the gas supply unit is connected to the support part.
